(19) United States
(12) Patent Application Publication
(10) Pub. No.: US 2026/0215228 A1
(43) Pub. Date: Jul. 23, 2026

(54) SEMICONDUCTOR DEVICE AND METHOD FOR FORMING THE SAME

(71) Applicant: Winbond Electronics Corp., Taichung City (TW)

(72) Inventors: Yu-Cheng Chen, Kaohsiung City (TW); Chia-Jou Chen, Kaohsiung City (TW)

(73) Assignee: Winbond Electronics Corp., Taichung City (TW)

(21) Appl. No.: 19/387,679

(22) Filed: Nov. 13, 2025

(30) Foreign Application Priority Data
Jan. 23, 2025 (TW) 114103156

(51) Int. Cl. H10P 74/20; H10P 74/00

(52) U.S. Cl. CPC H10P 74/207; H10P 74/273

(57) ABSTRACT

The present disclosure provides a semiconductor device and a method thereof. A first die including a first interconnection structure formed on a first region of a substrate is provided. A second die including a second interconnection structure formed on a second region, different from the first region, of the substrate is provided, wherein the first interconnection structure and the second interconnection structure are covered by a first dielectric layer formed on the substrate. A first and test structures respectively and electrically connected to the first and second interconnection structures are formed on the first interconnection structure and the second interconnection structure, respectively. The first test structure includes a first test pad and a first connection pad electrically connected to the first test pad. The second test structure includes a second test pad and a second connection pad electrically connected to the second test pad.

### CROSS-REFERENCE TO RELATED APPLICATION

This application claims the priority benefit of Taiwan application serial no. 114103156, filed on January, 23 2025. The entirety of the above-mentioned patent application is hereby incorporated by reference herein and made a part of this specification.

### BACKGROUND

### Technical Field

The present invention is related to a semiconductor device and a method for forming the same.

### Description of Related Art

System on-a-chip (SoC) is required to operate at high speed along with low power consumption. To meet the requirements, on-chip transistors are sized down, operating at lower power supply voltages, and thus a current density is increased accordingly. As such, a large voltage drop is generated through the high current density along with the fast switching of transistors. The voltage drop affects the circuit operation as being a power supply noise. Moreover, lower supply voltage relatively lowers the design margin for voltage fluctuations. Therefore, the power supply noise is one of the most serious concerns in the modern low voltage integrated circuits.

In the typical flip-chip packages, multi-layer ceramic capacitors (MLCC) are disposed near the conductive elements as being a “dam” of temporarily charging and discharging, which regulates the current in a circuit and prevents the electromagnetic interference between components. Since the thickness of a single dielectric and the number of stacked layers are related to the capacitance value, technology for thinning single layer and stacking more layers is important.

However, the effect of MLCC is limited by the parasitic elements, such as being limited by an equivalent series inductance (ESL) and an equivalent series resistance (ESR), and may also be affected by factors such as high temperature, frequency, or DC bias.

As the sizes of electronic devices continue to shrink and the requirements for the electronic device performance continue to increase, those skilled in the art are intended to dispose small capacitors between conductive elements, such as silicon capacitors (Si-Cap) that use silicon material as an insulator and are manufactured by the semiconductor technology, which may reduce the influences coming from the reduction of the power/ground balls, and may provide a current to a high-speed application processor in a quick and a stable manners as well.

### SUMMARY

An embodiment of the present invention provides a method of forming a semiconductor device, which includes following steps. A first die including a first interconnect structure formed on a first region of a substrate is provided. A second die including a second interconnect structure formed on a second region of the substrate is provided, wherein the second region is different from the first region, and the second interconnect structure and the first interconnect structure are covered by a first dielectric layer formed on the substrate. A first test structure electrically connected to the first interconnect structure and a second test structure electrically connected to the second interconnect structure are formed on the first interconnect structure and the second interconnect structure, respectively, wherein the first test structure includes a first test pad and a first connection pad electrically connected to the first test pad, and the second test structure includes a second test pad and a second connection pad electrically connected to the second test pad.

An embodiment of the present invention provides a semiconductor device including a first die, a second die, a first dielectric layer, and a first connection pad. The first die includes a first interconnect structure disposed on a first region of a substrate. The second die includes a second interconnect structure disposed on a second region of the substrate, wherein the second region is different from the first region. The first dielectric layer is on the substrate and covers the first interconnect structure and the second interconnect structure. The first connection pad is on the first interconnect structure and electrically connected to the first interconnect structure, wherein the first dielectric layer includes a first opening and a second opening adjacent to the first opening above the first interconnect structure, the first opening has a bottom surface defined by the first connection pad, and the second opening has a bottom surface defined by the first dielectric layer, and wherein a depth of the first opening is less than a depth of the second opening.

### BRIEF DESCRIPTION OF THE DRAWINGS

FIG. 1A and FIG. 2 to FIG. 5 are schematic cross-sectional views of a method of forming a semiconductor device according to an embodiment of the present invention.

FIG. 1B is a schematic top view of the first test structure illustrated in FIG. 1A according to an embodiment.

FIG. 6A is a schematic top view of the first conductive via illustrated in FIG. 5 according to an embodiment.

FIG. 6B is a schematic top view of the second conductive via illustrated in FIG. 5 according to an embodiment.

### DESCRIPTION OF THE EMBODIMENTS

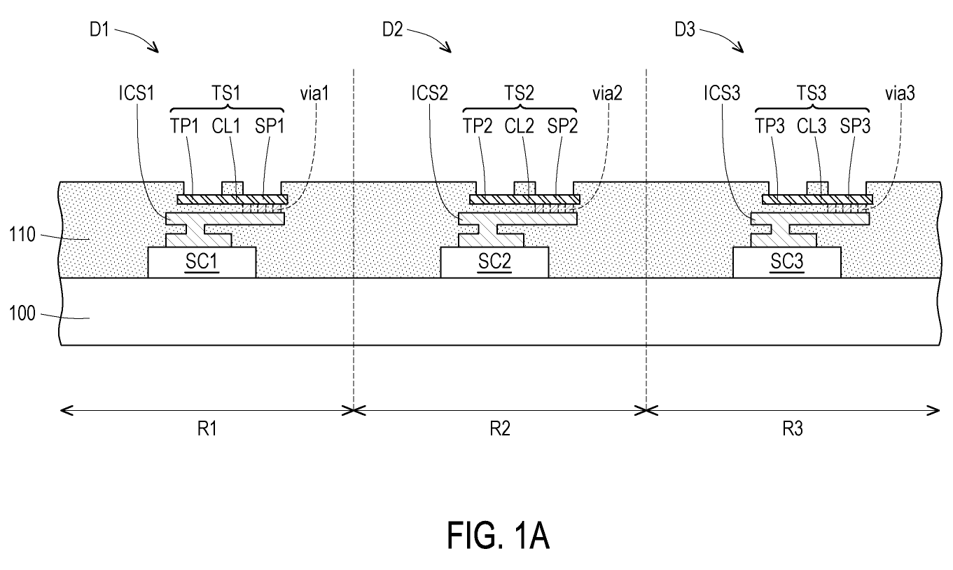

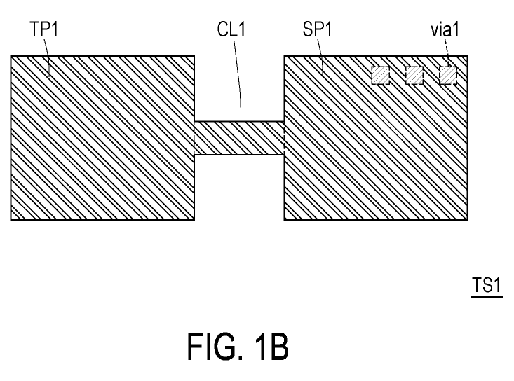

Firstly, referring to FIG. 1A, dies D1, D2 and D3 are provided. The dies D1, D2 and D3 include interconnect structures ICS1, ICS2 and ICS3 formed on regions R1, R2 and R3 of a substrate 100, respectively. The regions R1, R2 and R3 are different from each other. In some embodiments, the dies D1, D2 and D3 may be formed in the regions R1, R2 and R3 of a wafer, respectively. In other words, the substrate 100 may be a substrate of an entire wafer. In some embodiments, the dies D1, D2 and D3 may be respectively formed in the regions R1, R2 and R3 of the substrate 100 through a front-end-of-line (FEOL) process and/or a back-end-of-line (BEOL) process.

The substrate 100 may include a semiconductor substrate or a semiconductor-on-insulator (SOI) substrate and a device layer formed on the semiconductor substrate or the SOI substrate.

The device layer may be a film layer where active components are formed therein. In some embodiments, the device layer may include active components such as N-type metal-oxide-semiconductors (NMOS), P-type metal-oxide-semiconductors (PMOS), or complementary metal-oxide-semiconductors (CMOS).

The interconnect structures ICS1, ICS2 and ICS3 may include conductive layers and at least one conductive via connecting these conductive layers. The conductive layers and/or conductive vias may include conductive materials such as metals or metal alloys. The metals and metal alloys may be, for example, Cu, Al, Ti, Ta, W, Pt, Cr, Mo, or alloys thereof.

The interconnect structures ICS1, ICS2 and ICS3 are covered by a first dielectric layer 110 formed on the substrate 100. The first dielectric layer 110 may include any suitable dielectric material. For example, the first dielectric layer 110 may include oxides, such as a tetraethyl orthosilicate (TEOS), a borophosphosilicate glass (BPSG), an oxide formed by a high-density plasma (HDP), an undoped silicate glass (USG), a phosphosilicate glass (PSG), an oxide formed by a spinning method such as a spin on glass (SOG) and a spin on dielectric (SOD), or an oxide formed by a high aspect ratio process (HARP).

In some embodiments, the dies D1, D2 and D3 may include passive components SC1, SC2 and SC3 formed in the first dielectric layer 110 and located on the regions R1, R2 the R3, respectively. In some embodiments, the passive components SC1, SC2 and SC3 may include resistance components. For example, the resistance components may be silicon capacitors (Si-Cap). The passive components SC1, SC2 and SC3 may be electrically connected to the interconnect structures ICS1, ICS2 and ICS3, respectively.

Then, a test structure TS1 electrically connected to the interconnect structure ICS1, a test structure TS2 electrically connected to the interconnect structure ICS2, and a test structure TS3 electrically connected to the interconnect structure ICS3 are formed on the interconnect structures ICS1, ICS2 and ICS3, respectively. The test structure TS1 includes a test pad TP1 and a connection pad SP1 electrically connected to the test pad TP1. The test structure TS2 includes a test pad TP2 and a connection pad SP2 electrically connected to the test pad TP2. The test structure TS3 includes a test pad TP3 and a connection pad SP3 electrically connected to the test pad TP3. The test pads TP1, TP2 and TP3 may include any suitable conductive materials. For example, test pads TP1, TP2 and TP3 may include metallic materials such as aluminum (Al). The connection pads SP1, SP2 and SP3 may include any suitable conductive materials, such as metallic materials (e.g., aluminum (Al)). In some embodiments, the test pads TP1, TP2 and TP3 and the connection pads SP1, SP2 and SP3 may be formed in the same process simultaneously.

As shown in FIG. 1A and FIG. 1B, the test structures TS1, TS2 and TS3 may include conductive wires CL1, CL2 and CL3 electrically connecting the test pads TP1, TP2 and TP3 and the connection pads SP1, SP2 and SP3. The conductive wires CL1, CL2 and CL3 may each include one end connected to the respective test pads TP1, TP2 and TP3 and another end connected to the respective connection pads SP1, SP2 and SP3. The conductive wires CL1, CL2 and CL3 may include any suitable conductive materials, such as metallic materials (e.g., aluminum (Al)). In some embodiments, the test pads TP1, TP2 and TP3, the conductive wires CL1, CL2 and CL3, and the connection pads SP1, SP2 and SP3 may be formed in the same process simultaneously.

The dies D1, D2 and D3 may respectively include conductive vias via1, via2 and via3 formed in the first dielectric layer 110 and electrically connecting the connection pads SP1, SP2 and SP3 to the interconnect structures ICS1, ICS2 and ICS3. In some embodiments, the conductive vias via1, via2 and via3 may be configured under the connection pads SP1, SP2 and SP3. The conductive vias via1, via2 and via3 may include conductive materials such as metals or metal alloys, for example, Cu, Al, Ti, Ta, W, Pt, Cr, Mo, or alloys thereof.

The first dielectric layer 110 may cover the test structures TS1, TS2, and TS3 and include a plurality of openings exposing the test pads TP1, TP2, and TP3 and the connection pads SP1, SP2, and SP3, respectively, wherein the conductive wires CL1, CL2, and CL3 are covered by the first dielectric layer 110 and are not exposed by the first dielectric layer 110. Subsequently, test probes TPB are capable of probing the test pads TP1, TP2, and TP3 through these openings to test the dies D1, D2 and D3.

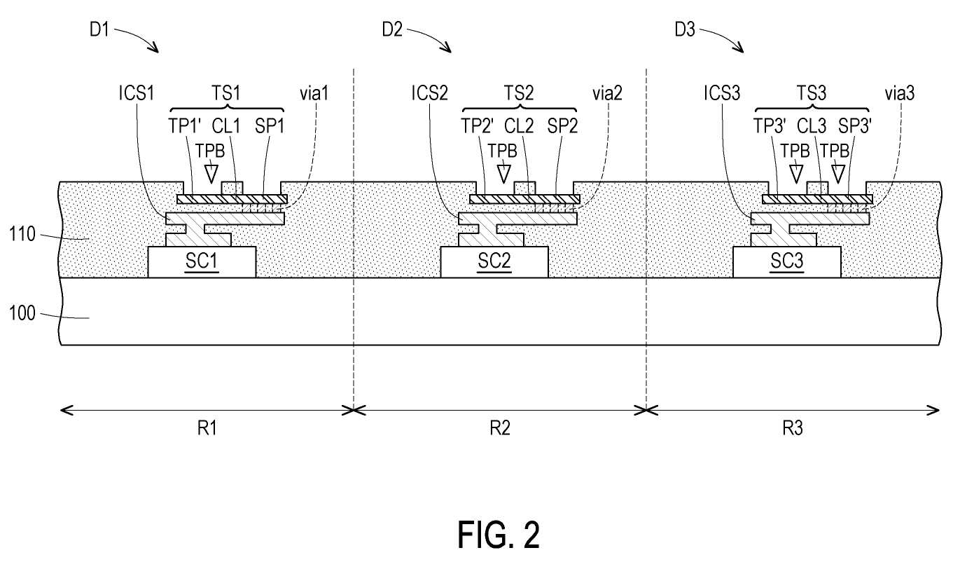

Next, referring to FIG. 2, the test pads TP1, TP2, and TP3 are probed by the test probes TPB to test the dies D1, D2, and D3. When a die is determined to be incompliant with a predetermined criterion after testing (also known as a bad die), the corresponding connection pad thereof is probed by the test probes TPB through the respective opening. For example, when the die D3 is determined to be the bad die after testing, the corresponding connection pad SP3 is probed by the test probe TPB. As a result, since the test pads TP1', TP2', and TP3' and the connection pad SP3' that are probed by the test probes TPB have the etching selectivity with respect to the connection pads SP1 and SP2 that are not probed by the test probes TPB, the connection pad (e.g., the connection pad SPb') of the bad die (e.g., the die D3) can be removed through a method such as a wet etch, and thereby preventing signals from connecting to the bad die that results to a failure of the semiconductor device including the bad die. In this embodiment, the bad die (i.e., being determined to be incompliant with the predetermined criterion) refers to the device performance (e.g., electrical performance) thereof does not meet the predetermined specifications but is not limited thereto.

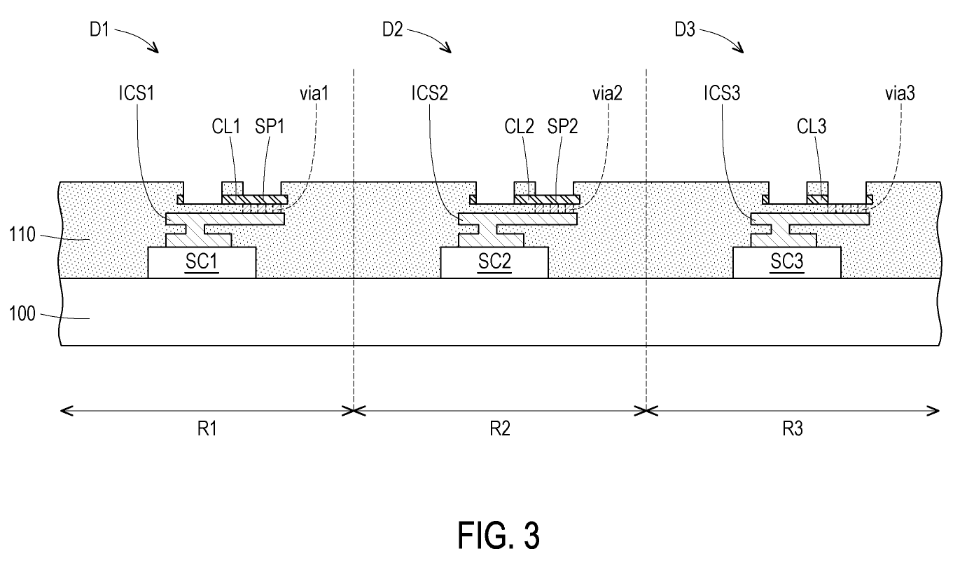

Subsequently, referring to FIG. 2 and FIG. 3, the test pads TP1’, TP2’, and TP3’ and the connection pad SP3' that are probed by the test probes TPB are removed. In some embodiments, the test pads TP1’, TP2’, and TP3’ and the connection pad SP3' that are probed by the test probes TPB are removed through a wet etch process. In some embodiments, hydrofluoric acid (DHF) may be used as an etchant to perform the wet etch process to remove the test pads TP1’, TP2’ and TP3’ and the connection pad SP3' that have been probed by the test probes TPB. In this embodiment, even the test pads TP1’, TP2’, and TP3’ and the connection pads SP1, SP2, and SP3' are made of the same material, the structure of the test pads TP1’, TP2’, and TP3’ and the connection pad SP3' that have been probed by the test probes TPB are damaged through probing, and therefore the test pads TP1’, TP2’, and TP3’ and the connection pad SP3' have good selectivity in the wet etch process with respect to the connection pads SP1 and SP2 that are not probed by the test probes TPB. For example, under the same conditions, the removal rates of the test pads TP1’, TP2’, and TP3’ and the connection pad SP3' will be greater than that of the connection pads SP1 and SP2 significantly.

As shown in FIG. 2 and FIG. 3, after removing the test pads TP1’, TP2’, and TP3’ and the connection pad SP3' that are probed by the test probes TPB, the openings in the first dielectric layer 110 that originally expose the test pads TP1, TP2, and TP3 and the connection pads SP1, SP2 and SP3 are formed to include first openings exposing the connection pads SP1 and SP2 and second openings (corresponding to the openings where the test pads TP1’, TP2’, and TP3’ and the connection pad SP3' are removed) having bottom surfaces defined by the first dielectric layer 110, wherein depths of the first openings are less than depths of the second openings. In some embodiments, after removing the test pads TP1’, TP2’, and TP3’ and the connection pad SP3' that are probed by the test probes TPB, the conductive via via1 and the conductive via via2 are covered by the connection pad SP1 and the connection pad SP2, respectively, whereas the conductive via via3 is exposed by one of second openings (corresponding to the opening where the connection pad SP3' is removed).

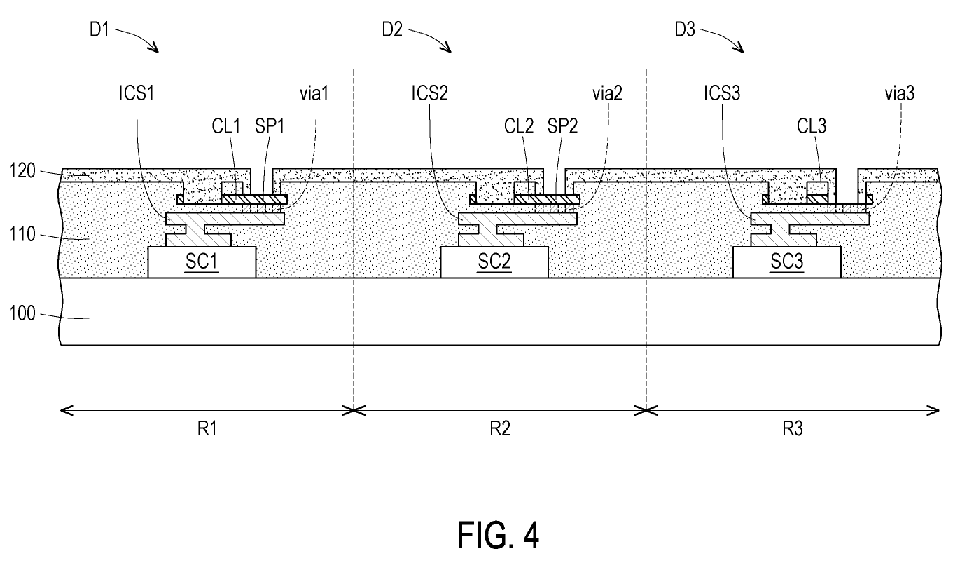

Next, referring to FIG. 4, a second dielectric layer 120 is formed on the first dielectric layer 110, wherein the second dielectric layer 120 fills into the above first openings and the second openings and covers the connection pads SP1 and SP2. The second dielectric layer 120 may include any suitable dielectric material such as polyimide (PI). Then, through a photolithography and etching processes, openings are formed in the second dielectric layer 120 to expose the connection pads SP1 and SP2, and an opening corresponding to the position of the previously removed connection pad SP3' is formed to expose the first dielectric layer 110.

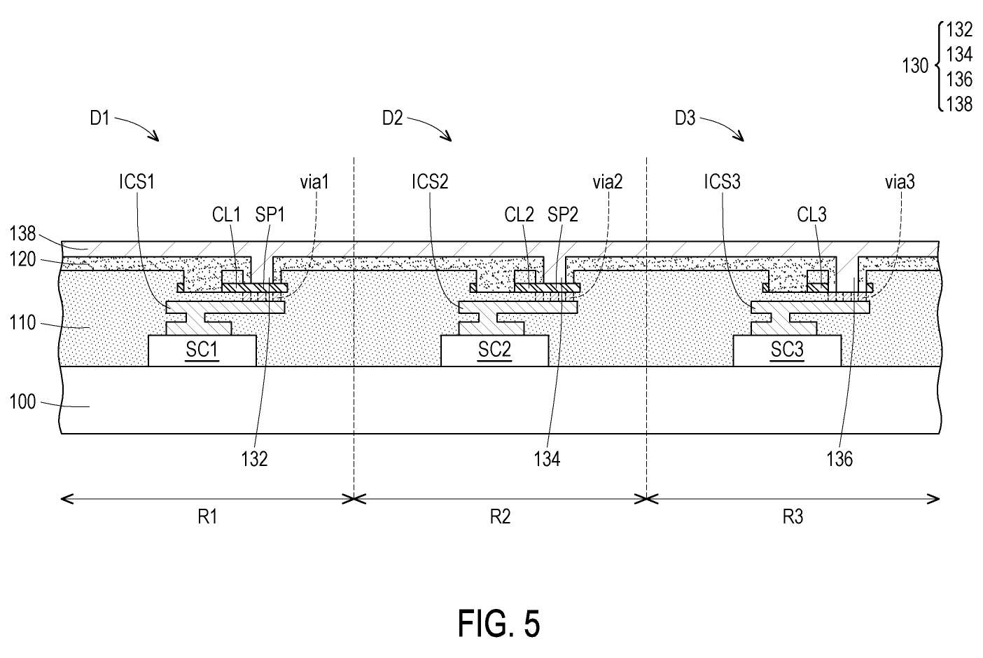

Then, referring to FIG. 5, a redistribution layer 130 is formed on the second dielectric layer 120, wherein the redistribution layer 130 may include vias b, 134 and 136 formed in the second dielectric layer 120 and a conductive layer 138 on and connecting the vias 132, 134 and 136. The vias 132 and 134 are formed in the openings that expose the connection pads SP1 and SP2 and are in contact with the connection pads SP1 and SP2, respectively. The via 136 is formed in the opening that corresponds to the position of the previously removed connection pad SP3' and exposes the first dielectric layer 110 and is in contact with the first dielectric layer 110. The vias 132, 134 and 136 and the conductive layer 138 may include any suitable conductive material, such as metals or metal alloys. The metals and metal alloys may be, for example, Cu, Al, Ti, Ta, W, Pt, Cr, Mo, or alloys thereof.

In this embodiment, the vias 132 and 134 are respectively formed over the interconnect structures ICS1 and ICS2 and may be electrically connected to the interconnect structures ICS1 and ICS2 through the first connection pads SP1 and SP2, respectively, whereas the via 136 is formed over the interconnect structure ICS3 and is electrically isolated from the interconnect structure ICS3. As a result, the passive components SC1 and SC2 of the dies D1 and D2 may be connected to each other through the vias 132 and 134 and may adjust the capacitance of the semiconductor device through, for example, series and/or parallel connections, while the via 136 is electrically isolated from the interconnect structure ICS3, and thus preventing the signals from connecting to the die D3 (being determined to be a bad die through the aforementioned test) that results to a failure in the semiconductor device including the bad die. In the case where the die D3 is determined to be the bad die, the connection pad SP3 electrically connected to the interconnect structure ICS3 may be removed through probing by the test probe TPB and then performing the wet etch process as mentioned above, so there is no need to adjust the photomask and/or mask (e.g., different combinations of photomasks and/or masks) to prevent the via 136 from being formed in the second dielectric layer 120 (e.g., there is no via hole for forming the via 136 formed in the second dielectric layer 120), and thereby preventing the signals from connecting to the die D3. As such, this disclosure may form the vias 132, 134 and 136 by using the same photomask and/or mask in the process without the needs to adjust the positions for the good dies (e.g., dies D1 and D2) and the bad dies (e.g., die D3), and thus is beneficial for improving the stability of the semiconductor device and saving the costs of the photomasks and/or masks.

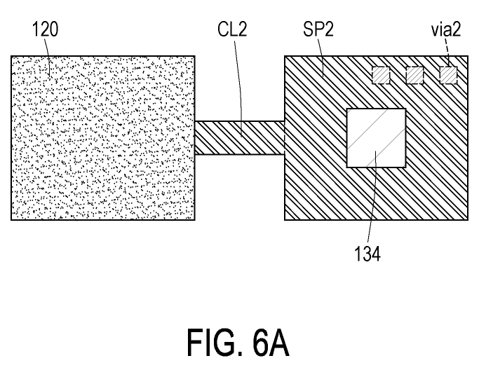

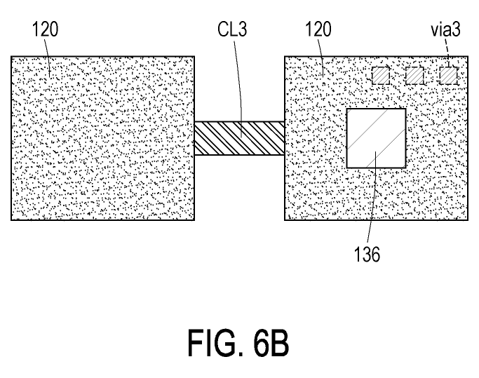

In some embodiments, as shown in FIG. 5 and FIG. 6A, one ends of the conductive wires CL1 and CL2 are in contact with the second dielectric layer 120 after the test pads TP1 and TP2 are removed, while the other ends of the conductive wires CL1 and CL2 remains in contact with the connection pads SP1 and SP2. In some embodiments, as shown in FIG. 5 and FIG. 6B, one end of the conductive wire CL3 is in contact with the second dielectric layer 120 after the test pad TP3 is removed, while the other end of the conductive wire CL3 is also in contact with the second dielectric layer 120 after the connection pad SP3' is removed.

In some embodiments, as shown in FIG. 5 and FIG. 6A and FIG. 6B, the vias 132 and 134 of the redistribution layer 130 penetrate through the second dielectric layer 120 to contact the corresponding connection pads SP1 and SP2, respectively, while the via 136 of the redistribution layer 130 penetrates through the second dielectric layer 120 to contact the first dielectric layer 110 but does not contact the conductive via via3 underneath. In some embodiments, the positions of the via 136 and the conductive via via3 are offset from each other and do not overlap with each other in the top view.

Hereinafter, a semiconductor device according to an embodiment of the disclosure will be illustrated with reference to FIG. 5, FIG. 6A and FIG. 6B. The semiconductor device of the embodiment may be formed by the method described above, but is not limited thereto.

Referring to FIG. 5, FIG. 6A and FIG. 6B, the semiconductor device may include a first die (e.g., die D1 or D2), a second die (e.g., die D3), a first dielectric layer 110, and a first connection pad (e.g., connection pad SP1 or SP2). The first die includes a first interconnect structure (e.g., interconnect structure ICS1 or ICS2) disposed on a first region (e.g., region R1 or R2) of the substrate 100. The second die includes a second interconnect structure (e.g., interconnect structure ICS3) disposed on a second region (e.g., region R3) of the substrate 100, wherein the second region is different from the first region. The first dielectric layer 110 is on the substrate 100 and covers the first interconnect structure (e.g., interconnect structure ICS1 or ICS2) and the second interconnect structure (e.g., interconnect structure ICS3). The first connection pad (e.g., connection pad SP1 or SP2) is on the first interconnect structure (e.g., interconnect structure ICS1 or ICS2) and is electrically connected to the first interconnect structure. The first dielectric layer 110 includes a first opening with a bottom surface defined by the first connection pad (e.g., connection pad SP1 or SP2) and a second opening with a bottom surface defined by the first dielectric layer 110 and adjacent to the first opening, above the first interconnect structure (e.g., interconnect structure ICS1 or ICS2), wherein the depth of the first opening is less than the depth of the second opening.

In some embodiments, the semiconductor device may further include a first conductive wire (e.g., conductive wire CL1 or CL2) disposed in the first dielectric layer 110 and connected to the first connection pad (e.g., connection pad SP1 or SP2), wherein the first conductive wire may be configured between the first opening and the second opening.

In some embodiments, the semiconductor device may further include a second dielectric layer 120 disposed on the first dielectric layer 110 and filling into the first opening and the second opening, wherein the first conductive wire (e.g., conductive wire CL1 or CL2) may include one end in contact with the second dielectric layer 120 and another end in contact with the first connection pad (e.g., connection pad SP1 or SP2).

In some embodiments, the semiconductor device may further include a redistribution layer 130 disposed on the second dielectric layer 120. The redistribution layer 130 may include a first via (e.g., via 132 or 134) penetrating through the second dielectric layer 120 in the first opening and contacting the first connection pad (e.g., connection pad SP1 or SP2).

In some embodiments, the first dielectric layer 110 includes a third opening and a fourth opening with bottom surfaces defined by the first dielectric layer 110 and adjacent to each other above the second interconnect structure (e.g., interconnect structure ICS3). The depth of the third opening is about equal to the depth of the fourth opening, and the second dielectric layer 120 fills into the third opening and the fourth opening. The semiconductor device may further include a second conductive wire (e.g., conductive wire CL3) disposed in the first dielectric layer 110 and configured between the third opening and the fourth opening, and the second conductive wire includes one end and another end respectively in contact with the second dielectric layer 120.

In some embodiments, the semiconductor device may further include a first conductive via and a second conductive via. The first conductive via (e.g., conductive via via1 or via2) may be disposed in the first dielectric layer 110 below the first connection pad (e.g., connection pad SP1 or SP2) and may electrically connect the first interconnect structure (e.g., interconnect structure ICS1 or ICS2) to the first connection pad. The second conductive via (e.g., conductive via via3) may be disposed in the first dielectric layer 110 below the fourth opening and may be electrically connected to the second interconnect structure (e.g., interconnect structure ICS3). As shown in FIG. 6B, the second conductive via (e.g., conductive via via3) may be covered by the second dielectric layer 120 filled into the fourth opening.

In some embodiments, the redistribution layer 130 may include a second via (e.g., via 136) penetrating through the second dielectric layer 120 in the fourth opening and contacting the first dielectric layer 110, wherein the second via does not contact the second conductive via (e.g., conductive via via3).

In summary, in the forgoing embodiments of the semiconductor device and the method of forming the same, the test structures are designed to include the test pads and the connection pads, and during the step of probing the test pads by the test probes to test the dies, the connection pads of the dies determined to be incompliant with the predetermined criterion (hereinafter referred to as the bad dies) are probing by the test probes again. As such, based on the test pads and the connection pads that have been probed by the test probes have the etching selectivity in the process such as a wet etch process with respect to the connection pads that have not been probed, the connection pads of the bad dies can be removed through a method such as wet etching, and thereby preventing the signals from connecting to the bad dies that results to a failure situation in the semiconductor device including such bad dies.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of forming a semiconductor device, comprising:
providing a first die comprising a first interconnect structure formed on a first region of a substrate;
providing a second die comprising a second interconnect structure formed on a second region of the substrate, wherein the second region is different from the first region, and the second interconnect structure and the first interconnect structure are covered by a first dielectric layer formed on the substrate; and
forming a first test structure electrically connected to the first interconnect structure and a second test structure electrically connected to the second interconnect structure on the first interconnect structure and the second interconnect structure, respectively, wherein the first test structure comprises a first test pad and a first connection pad electrically connected to the first test pad, and the second test structure comprises a second test pad and a second connection pad electrically connected to the second test pad.

2. The method according to claim 1, further comprising:
probing the first test pad and the second test pad with a test probe to test the first die and the second die; and
when the second die is determined to be incompliant with a predetermined criterion after testing, probing the second connection pad with the test probe.

3. The method according to claim 2, further comprising:
removing the first test pad, the second test pad, and the second connection pad that are probed by the test probe.

4. The method according to claim 3, wherein the first test pad, the second test pad, and the second connection pad that are probed by the test probe are removed through a wet etch process.

5. The method according to claim 4, wherein the first test pad, the second test pad, and the second connection pad that are probed by the test probe have etching selectivity in the wet etch process with respect to the first connection pad that is not probed by the test probe.

6. The method according to claim 3, further comprising:
forming a second dielectric layer, covering the first connection pad, on the first dielectric layer; and
forming a redistribution layer on the second dielectric layer, wherein the redistribution layer comprises a first via and a second via formed in the second dielectric layer, the first via is in contact with the first connection pad, and the second via is in contact with the first dielectric layer.

7. The method according to claim 6, wherein the first via is formed over the first interconnect structure and is electrically connected to the first interconnect structure through the first connection pad, and the second via is formed over the second interconnect structure and is electrically isolated from the second interconnect structure.

8. The method according to claim 6, wherein the first test structure comprises a first conductive wire comprising one end connected to the first test pad and another end connected to the first connection pad, and the one end of the first conductive wire is in contact with the second dielectric layer after the first test pad is removed.

9. The method according to claim 6, wherein the second test structure comprises a second conductive wire comprising one end connected to the second test pad and another end connected to the second connection pad, and the one end and the another end of the second conductive wire are both in contact with the second dielectric layer after the second test pad and the second connection pad are removed.

10. The method according to claim 3, wherein the first dielectric layer covers the first test structure and the second test structure and comprises a plurality of openings exposing the first test pad, the first connection pad, the second test pad, and the second connection pad, respectively, and the test probe is in contact with the first test pad, the second test pad, and the second connection pad through the plurality of openings.

11. The method according to claim 10, further comprising:
after removing the first test pad, the second test pad, and the second connection pad that are probed by the test probe, the plurality of openings comprise a first opening exposing the first connection pad and a plurality of second openings having bottom surfaces defined by the first dielectric layer, wherein a depth of the first opening is less than a depth of each second opening.

12. The method according to claim 11, further comprising:
forming a first conductive via in the first dielectric layer electrically connecting the first interconnect structure to the first connection pad, and a second conductive via in the first dielectric layer electrically connecting the second interconnect structure to the second connection pad,
wherein after removing the first test pad, the second test pad, and the second connection pad that are probed by the test probe, the second conductive via is exposed by one of the plurality of second openings.

13. The method according to claim 12, further comprising:
after removing the first test pad, the second test pad, and the second connection pad that are probed by the test probe, forming a second dielectric layer on the first dielectric layer, wherein the second dielectric layer fills in the first opening and the plurality of second openings, and the second dielectric layer covers the second conductive via exposed by the one of the plurality of second openings; and
forming a redistribution layer on the second dielectric layer, wherein the redistribution layer comprises a first via and a second via formed in the second dielectric layer, the first via is in contact with the first connection pad, and the second via is not in contact with the second conductive via.

14. A semiconductor device, comprising:
a first die comprising a first interconnect structure disposed on a first region of a substrate;
a second die comprising a second interconnect structure disposed on a second region of the substrate, wherein the second region is different from the first region;
a first dielectric layer on the substrate and covering the first interconnect structure and the second interconnect structure; and
a first connection pad on the first interconnect structure and electrically connected to the first interconnect structure,
wherein the first dielectric layer comprises a first opening and a second opening adjacent to the first opening over the first interconnect structure, the first opening has a bottom surface defined by the first connection pad, and the second opening has a bottom surface defined by the first dielectric layer, wherein a depth of the first opening is less than a depth of the second opening.

15. The semiconductor device according to claim 14, further comprising:
a first conductive wire disposed in the first dielectric layer and connected to the first connection pad, wherein the first conductive wire is configured between the first opening and the second opening.

16. The semiconductor device according to claim 15, further comprising:
a second dielectric layer disposed on the first dielectric layer and filling into the first opening and the second opening,
wherein the first conductive wire comprises one end in contact with the second dielectric layer and another end in contact with the first connection pad.

17. The semiconductor device according to claim 16, further comprising:
a redistribution layer disposed on the second dielectric layer and comprising a first via penetrating through the second dielectric layer in the first opening and contacting the first connection pad.

18. The semiconductor device according to claim 17, wherein the first dielectric layer comprises a third opening and a fourth opening adjacent to each other over the second interconnect structure, and both of the third opening and the fourth opening have bottom surfaces defined by the first dielectric layer, a depth of the third opening is about equal to a depth of the fourth opening, and the second dielectric layer fills into the third opening and the fourth opening, and
the semiconductor device further comprises:
a second conductive wire disposed in the first dielectric layer and configured between the third opening and the fourth opening, and the second conductive wire comprises one end and another end respectively in contact with the second dielectric layer.

19. The semiconductor device according to claim 18, further comprising:
a first conductive via disposed in the first dielectric layer under the first connection pad and electrically connecting the first interconnect structure to the first connection pad; and
a second conductive via disposed in the first dielectric layer under the fourth opening and electrically connected to the second interconnect structure, wherein the second conductive via is covered by the second dielectric layer filled in the fourth opening.

20. The semiconductor device according to claim 19, wherein the redistribution layer comprises a second via penetrating through the second dielectric layer in the fourth opening and contacting the first dielectric layer, wherein the second via is not in contact with the second conductive via.
